(19) United States
(12) Patent Application Publication
(10) Pub. No.: US 2025/0055296 A1
(43) Pub. Date: Feb. 13, 2025

(54) BATTERY MANAGEMENT SYSTEM

(71) Applicant: Nuvoton Technology Corporation Japan, Kyoto (JP)

(72) Inventors: Susumu YOSHIKAWA, Shiga (JP); Hitoshi KOBAYASHI, Osaka (JP); Keiichi FUJII, Shiga (JP); Akira KAWABE, Osaka (JP)

(21) Appl. No.: 18/925,979

(22) Filed: Oct. 24, 2024

Related U.S. Application Data
(63) Continuation of application No. PCT/JP2023/016322, filed on Apr. 25, 2023.
(60) Provisional application No. 63/335,435, filed on Apr. 27, 2022.

(51) Int. Cl. H02J 7/00

(52) U.S. Cl. CPC H02J 7/0048; H02J 7/00032; H02J 7/0013

(57) ABSTRACT

A BMS includes: a BMU that manages a battery assembly; a first CMU that monitors one or more battery cells included in the battery assembly; and a second CMU that monitors the one or more battery cells monitored by the first CMU. The first CMU includes a wireless communication circuit and a communication antenna for communicating with the BMU. The second cell monitoring circuit CMU includes a power line communication circuit, for communicating with the BMU, that uses a power line in the battery assembly.

### CROSS REFERENCE TO RELATED APPLICATIONS

This is a continuation application of PCT International Application No. PCT/JP2023/016322 filed on Apr. 25, 2023, designating the United States of America, which is based on and claims priority of U.S. Provisional Patent Application No. 63/335,435 filed on Apr. 27, 2022. The entire disclosures of the above-identified applications, including the specifications, drawings, and claims are incorporated herein by reference in their entirety.

### FIELD

The present disclosure relates to a battery management system for managing a battery assembly.

### BACKGROUND

Patent Literature (PTL) 1 discloses a technique for managing the battery cells of a battery assembly.

### CITATION LIST

### Patent Literature

PTL 1: U.S. Patent Application Publication No. 2016/0268642

### SUMMARY

### Technical Problem

In a battery management system such as the system disclosed in PTL 1, communication is performed between a management circuit that manages the battery assembly and a plurality of monitoring circuits that monitor the battery assembly. However, there is a risk that communication may fail due to disconnection of communication lines, external noise, or interactions between the communications occurring between the management circuit and each of the plurality of monitoring circuits.

In view of the above, the present disclosure provides a battery management system that can increase the redundancy of communication within the battery management system.

### Solution to Problem

A battery management system according to the present disclosure is for managing a battery assembly, and includes: a management circuit that manages the battery assembly; a first cell monitoring circuit that monitors one or more battery cells included in the battery assembly; and a second cell monitoring circuit that monitors the one or more battery cells monitored by the first cell monitoring circuit. The first cell monitoring circuit includes a wireless communication circuit and a communication antenna for communicating with the management circuit, and the second cell monitoring circuit includes a power line communication circuit, for communicating with the management circuit, that uses a power line in the battery assembly.

A battery management system according to the present disclosure is for managing a battery assembly, and includes: a management circuit that manages the battery assembly; and a plurality of cell monitoring circuits that monitor one or more battery cells included in the battery assembly. Each of the plurality of cell monitoring circuits is connected to one or more other cell monitoring circuits among the plurality of cell monitoring circuits via wired communication, and at least two cell monitoring circuits among the plurality of cell monitoring circuits include a wireless communication circuit and a communication antenna for communicating with the management circuit.

General or specific aspects of the present disclosure may be realized as a system, a method, an integrated circuit, a computer program, a computer-readable recording medium such as CD-ROM, or any given combination thereof.

### Advantageous Effects

With the battery management system according to one aspect of the present disclosure, the redundancy of communication within the battery management system can be increased.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is an external view illustrating one example of a battery management system according to an embodiment of the present disclosure.

FIG. 2 is a configuration diagram illustrating a first example of a battery management system according to an embodiment of the present disclosure.

FIG. 3A is a configuration diagram illustrating one example of a wireless communication circuit included in a first cell monitoring circuit.

FIG. 3B is a configuration diagram illustrating one example of a voltage monitoring circuit included in a first cell monitoring circuit.

FIG. 4A is a configuration diagram illustrating one example of a power line communication circuit included in a second cell monitoring circuit.

FIG. 4B is a configuration diagram illustrating one example of a voltage monitoring circuit included in a second cell monitoring circuit.

FIG. 5 is a configuration diagram illustrating one example of a current measurement circuit included in a current monitoring circuit.

FIG. 6A is a configuration diagram illustrating one example of a wireless communication circuit included in a management circuit.

FIG. 6B is a configuration diagram illustrating one example of a power line communication circuit included in a management circuit.

FIG. 6C is a configuration diagram illustrating one example of an MCU included in a management circuit.

FIG. 7 is a configuration diagram illustrating a second example of a battery management system according to an embodiment of the present disclosure.

FIG. 8A is a configuration diagram illustrating one example of a current measurement circuit included in a first current monitoring circuit.

FIG. 8B is a configuration diagram illustrating one example of a wireless communication circuit included in a first current monitoring circuit.

FIG. 9 is a configuration diagram illustrating a third example of a battery management system according to an embodiment of the present disclosure.

FIG. 10 is a configuration diagram illustrating a fourth example of a battery management system according to an embodiment of the present disclosure.

FIG. 11 is a configuration diagram illustrating a fifth example of a battery management system according to an embodiment of the present disclosure.

### DESCRIPTION OF EMBODIMENT(S)

Hereinafter, one or more embodiments of the present disclosure will be described in detail with reference to the drawings.

Each embodiment described below illustrates a general or specific example. The numerical values, shapes, materials, elements, the arrangement and connection of the elements, etc., shown in the following embodiments are mere examples, and therefore do not limit the scope of the present disclosure.

### Embodiment

Hereinafter, a battery management system according to an embodiment of the present disclosure will be described.

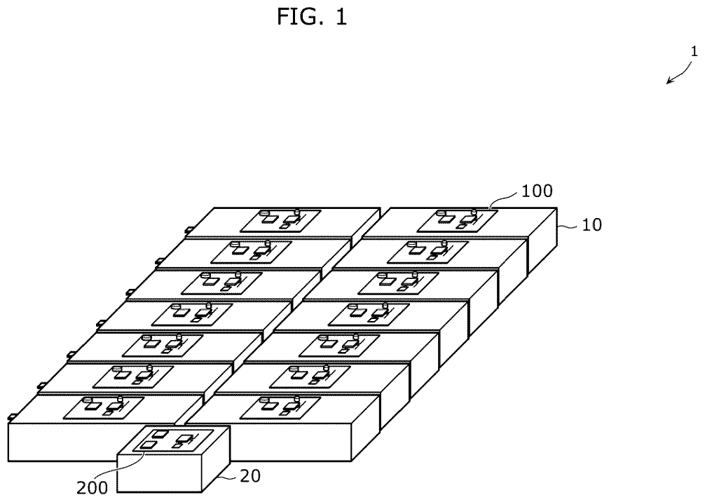

FIG. 1 is an external view illustrating one example of battery management system (hereinafter also “BMS”) 1 according to an embodiment of the present disclosure.

BMS 1 is a system for managing a battery assembly. For example, BMS 1 manages the state of charge (SOC), state of health (SOH), and state of power (SOP) of the battery assembly. BMS 1 monitors anomalies in the battery assembly. BMS 1 includes management circuit 200 that manages the battery assembly, and a plurality of monitoring circuits 100 that monitor the battery assembly. For example, the battery assembly includes a plurality of battery packs 10 connected in series or parallel. Battery pack 10 includes one or more battery cells. When battery pack 10 includes a plurality of battery cells, the plurality of battery cells are connected in series.

For example, monitoring circuit 100 is disposed on each of the plurality of battery packs 10. Specific examples of monitoring circuit 100, namely cell monitoring units (CMUs) 101 to 109 and current monitoring units (CMUs) 301 to 303, will be described later.

For example, management circuit 200 is connected to a battery assembly via junction box 20. Specific examples of management circuit 200, namely battery management units (BMUs) 201 to 203, will be described later.

Hereinafter, first through fifth examples of BMS 1 according to an embodiment of the present disclosure will be given.

### First Example

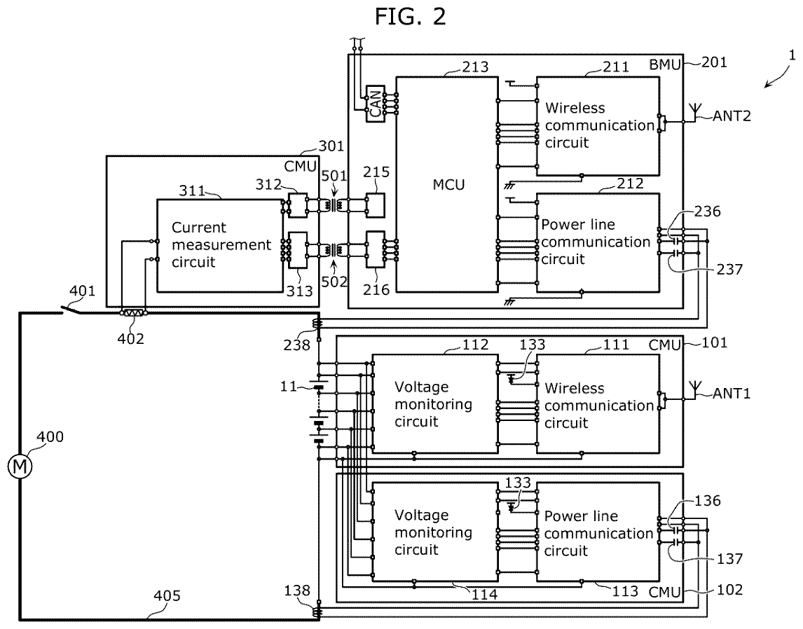

First, the first example will be explained with reference to FIG. 2 through FIG. 6C.

FIG. 2 is a configuration diagram illustrating a first example of BMS 1 according to an embodiment of the present disclosure.

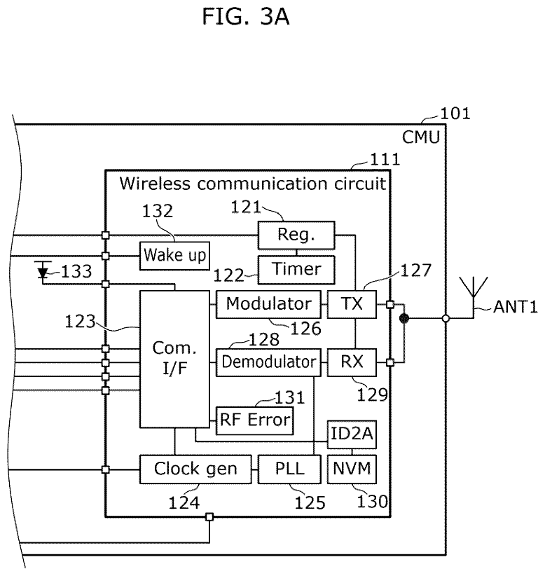

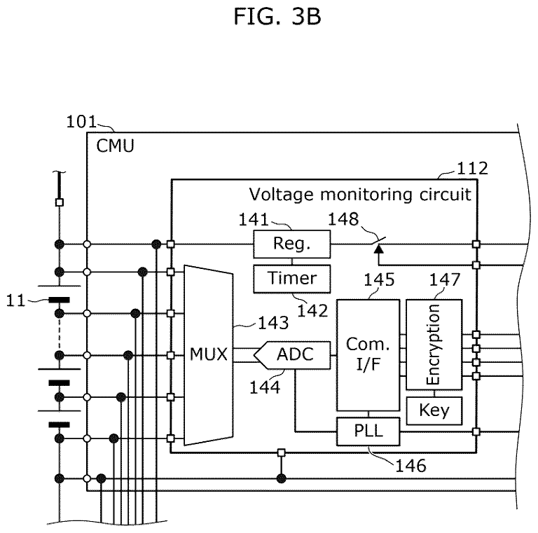

FIG. 3A is a configuration diagram illustrating one example of wireless communication circuit 111 included in a first cell monitoring circuit (CMU 101). Note that FIG. 3A also illustrates elements peripheral to wireless communication circuit 111 in the configuration diagram of FIG. 2.

FIG. 3B is a configuration diagram illustrating one example of voltage monitoring circuit 112 included in the first cell monitoring circuit (CMU 101). Note that FIG. 3B also illustrates elements peripheral to voltage monitoring circuit 112 in the configuration diagram of FIG. 2.

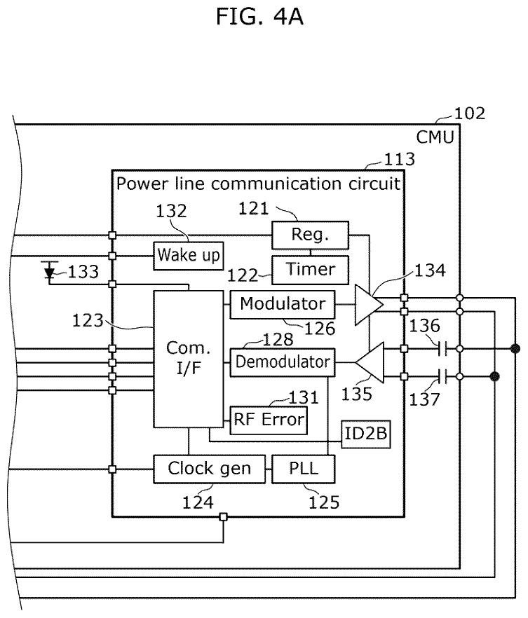

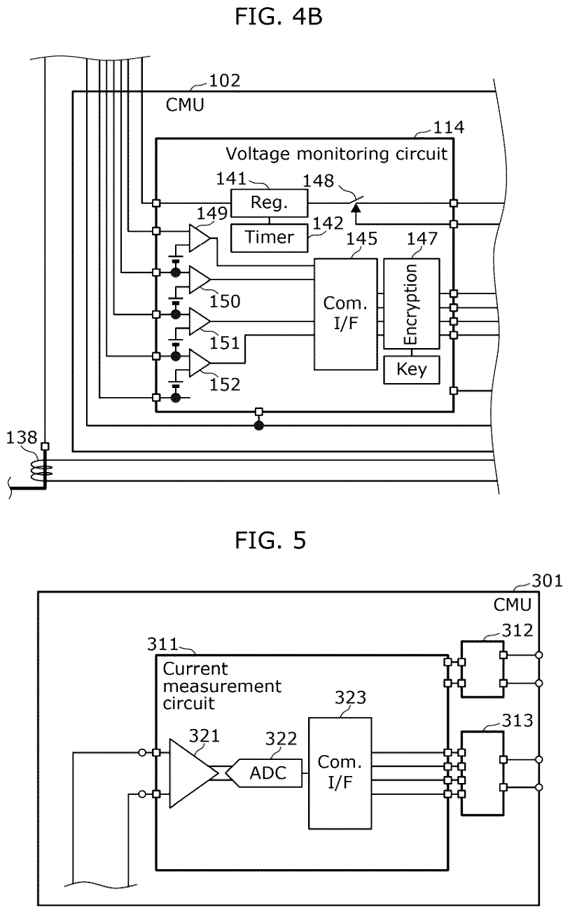

FIG. 4A is a configuration diagram illustrating one example of power line communication circuit 113 included in a second cell monitoring circuit (CMU 102). Note that FIG. 4A also illustrates elements peripheral to power line communication circuit 113 in the configuration diagram of FIG. 2.

FIG. 4B is a configuration diagram illustrating one example of voltage monitoring circuit 114 included in the second cell monitoring circuit (CMU 102). Note that FIG. 4B also illustrates elements peripheral to voltage monitoring circuit 114 in the configuration diagram of FIG. 2.

FIG. 5 is a configuration diagram illustrating one example of current measurement circuit 311 included in the current monitoring circuit (CMU 301). Note that FIG. 5 also illustrates elements peripheral to current measurement circuit 311 in the configuration diagram of FIG. 2.

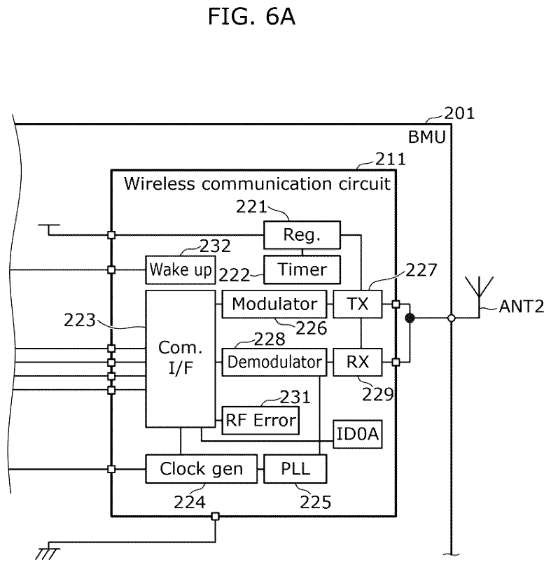

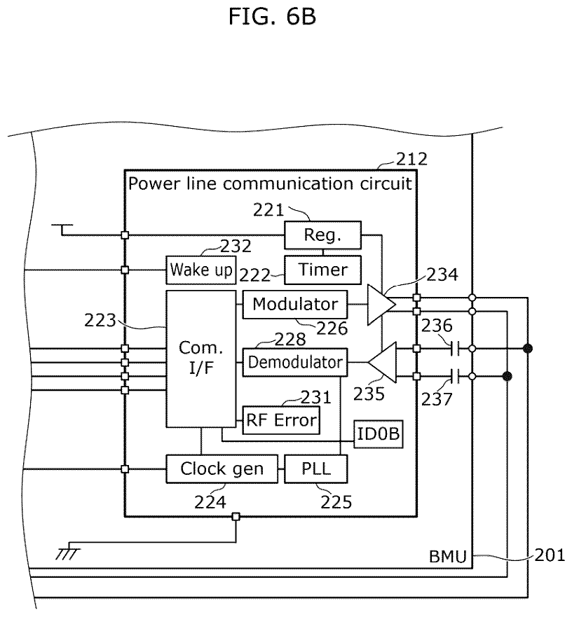

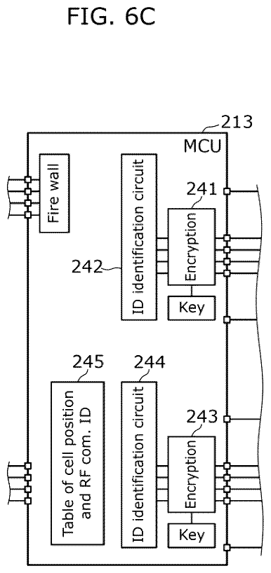

FIG. 6A is a configuration diagram illustrating one example of wireless communication circuit 211 included in the management circuit (BMU 201). Note that FIG. 6A also illustrates elements peripheral to wireless communication circuit 211 in the configuration diagram of FIG. 2.

FIG. 6B is a configuration diagram illustrating one example of power line communication circuit 212 included in the management circuit (BMU 201). Note that FIG. 6B also illustrates elements peripheral to power line communication circuit 212 in the configuration diagram of FIG. 2.

FIG. 6C is a configuration diagram illustrating one example of MCU 213 included in the management circuit (BMU 201). Note that FIG. 6C also illustrates elements peripheral to MCU 213 in the configuration diagram of FIG. 2.

In the first example, focusing on one battery pack 10 among the plurality of battery packs 10, FIG. 2 illustrates a plurality of battery cells 11 included in one battery pack 10 in the battery assembly as the one or more battery cells included in the battery assembly. CMUs 101 and 102 as well as CMU 301 are illustrated as monitoring circuit 100, and BMU 201 is illustrated as management circuit 200. Motor 400 is illustrated as a load to which power is supplied from the battery assembly. Moreover, power line 405 (bus bar) connecting the battery assembly and motor 400, and relay 401 and shunt resistor 402 inserted in power line 405 are also illustrated.

Relay 401 is a switch for interrupting current flowing in power line 405. For example, relay 401 is turned off to interrupt current flowing in power line 405 when the current monitored by CMU 301 is determined to be anomalous. Also, for example, relay 401 is turned off to interrupt current flowing in power line 405 when the voltage monitored by CMU 101 or 102 is determined to be anomalous.

Shunt resistor 402 is a resistor for measuring current flowing in power line 405.

CMU 101 is one example of a first cell monitoring circuit that monitors one or more battery cells included in the battery assembly. For example, CMU 101 monitors the voltage of each of a plurality of battery cells 11. CMU 102 is one example of a second cell monitoring circuit that monitors one or more battery cells monitored by the first cell monitoring circuit. For example, CMU 102 monitors the voltage of each of the plurality of battery cells 11 that CMU 101 monitors. CMU 101 and CMU 102 each monitor the same battery cells 11.

As illustrated in FIG. 2, CMU 101 includes wireless communication circuit 111 and communication antenna ANT1 for communicating with BMU 201. CMU 101 includes voltage monitoring circuit 112 that monitors the voltage of each of the plurality of battery cells 11. For example, wireless communication circuit 111 and voltage monitoring circuit 112 are each implemented by different integrated circuits (ICs). Note that wireless communication circuit 111 and voltage monitoring circuit 112 may be implemented by a single IC.

As illustrated in FIG. 3A, wireless communication circuit 111 includes voltage conversion circuit (Reg.) 121, timer circuit (Timer) 122, communications interface (Com. I/F) 123, clock generation circuit (Clock gen) 124, phase-locked loop (PLL) 125, modulation circuit (Modulator) 126, transmission circuit (Tx) 127, demodulation circuit (Demodulator) 128, reception circuit (Rx) 129, non-volatile memory (NVM) 130, communication error determination circuit (RF Error) 131, and wake-up circuit (Wake up) 132.

Voltage conversion circuit 121 is a circuit that converts the voltage input from voltage monitoring circuit 112 to a voltage for operating wireless communication circuit 111 and outputs the converted voltage.

Timer circuit 122 is a circuit that counts time. For example, timer circuit 122 is used to operate wireless communication circuit 111 intermittently.

Communications interface 123 is an interface for performing communication between wireless communication circuit 111 and voltage monitoring circuit 112. Note that when wireless communication circuit 111 and voltage monitoring circuit 112 are implemented by a single IC, communications interface 123 may be omitted.

Clock generation circuit 124 is a circuit for generating a clock in CMU 101.

Phase-locked loop 125 is a circuit that adjusts the phase of a local signal to match the phase of a received signal.

Modulation circuit 126 is a circuit that modulates signals to be transmitted to BMU 201.

Transmission circuit 127 is a circuit for transmitting signals to BMU 201. Transmission circuit 127 transmits signals to BMU 201 via communication antenna ANT1.

Demodulation circuit 128 is a circuit that demodulates signals received from BMU 201.

Reception circuit 129 is a circuit for receiving signals from BMU 201. Reception circuit 129 receives signals from BMU 201 via communication antenna ANT1.

Non-volatile memory 130 stores identification information of wireless communication circuit 111. For example, non-volatile memory 130 stores the identification information “ID2A”. Note that FIG. 3A illustrates non-volatile memory 130, but the identification information may be stored in any memory included in wireless communication circuit 111. The illustration of the memory in which identification information is stored is omitted for the power line communication circuit and the wireless communication circuit, which will be described later.

Communication error determination circuit 131 is a circuit that determines whether an anomaly has occurred in the communication between CMU 101 and BMU 201.

Wake-up circuit 132 is a circuit for activating wireless communication circuit 111.

As illustrated in FIG. 2, CMU 101 may include LED 133, for example. For example, LED 133 emits light when wireless communication circuit 111 satisfies a specific condition.

As illustrated in FIG. 3B, voltage monitoring circuit 112 includes voltage conversion circuit (Reg.) 141, timer circuit (Timer) 142, multiplexer (MUX) 143, AD converter (ADC) 144, communications interface (Com. I/F) 145, phase-locked loop (PLL) 146, encryption circuit (Encryption) 147, and switch 148.

Voltage conversion circuit 141 is a circuit that converts the voltage input from the battery assembly to a voltage for operating voltage monitoring circuit 112 and outputs the converted voltage.

Timer circuit 142 is a circuit that counts time. For example, timer circuit 142 is a circuit for operating wireless communication circuit 111 intermittently. Although CMU 101 includes timer circuits 122 and 142 in wireless communication circuit 111 and voltage monitoring circuit 112, respectively, CMU 101 need not include both timer circuits 122 and 142. Stated differently, wireless communication circuit 111 need not include timer circuit 122, or voltage monitoring circuit 112 need not include timer circuit 142.

Multiplexer 143 selects one battery cell 11 from among the plurality of battery cells 11 and outputs the terminal voltage of the selected battery cell 11. Stated differently, multiplexer 143 can output the voltage of each of the plurality of battery cells 11.

AD converter 144 converts the voltage value (analog value) of battery cell 11 selected by multiplexer 143 into a digital value.

Communications interface 145 is an interface for performing communication between wireless communication circuit 111 and voltage monitoring circuit 112. Note that when wireless communication circuit 111 and voltage monitoring circuit 112 are implemented by a single IC, communications interface 145 may be omitted.

Phase-locked loop 146 is a circuit that adjusts the phase of a local signal to match the phase of a received signal.

Encryption circuit 147 is a circuit that encrypts and decrypts signals. For example, encryption circuit 147 encrypts signals to be transmitted to wireless communication circuit 111 and ultimately to BMU 201, using an encryption key (Key).

Switch 148 is a switch that toggles on and off the power supply to wireless communication circuit 111, and is, for example, a transistor or the like. Switch 148 is controlled by a control signal from wake-up circuit 132. Wake-up circuit 132 can control the activation of wireless communication circuit 111 by controlling switch 148 to control the power supply to wireless communication circuit 111.

CMU 101 detects the voltage value of each of the plurality of battery cells 11 using voltage monitoring circuit 112, and transmits the detected voltage values to BMU 201 using wireless communication circuit 111.

As illustrated in FIG. 2, CMU 102 includes power line communication circuit 113 that uses power line 405 (for example, a bus bar) in the battery assembly for communicating with BMU 201. CMU 102 includes voltage monitoring circuit 114 that monitors the voltage of each of the plurality of battery cells 11. For example, power line communication circuit 113 and voltage monitoring circuit 114 are each implemented by different ICs. Note that power line communication circuit 113 and voltage monitoring circuit 114 may be implemented by a single IC.

As illustrated in FIG. 2 and FIG. 4A, power line communication circuit 113 includes voltage conversion circuit (Reg.) 121, timer circuit (Timer) 122, communications interface (Com. I/F) 123, clock generation circuit (Clock gen) 124, phase-locked loop (PLL) 125, modulation circuit (Modulator) 126, demodulation circuit (Demodulator) 128, communication error determination circuit (RF Error) 131, wake-up circuit (Wake up) 132, amplification circuits 134 and 135, capacitors 136 and 137, and coil 138. FIG. 4A illustrates “ID2B” as the identification information of power line communication circuit 113.

The explanation of the functions of voltage conversion circuit 121, timer circuit 122, communications interface 123, clock generation circuit 124, phase-locked loop 125, modulation circuit 126, demodulation circuit 128, communication error determination circuit 131, and wake-up circuit 132 included in power line communication circuit 113 is the same as the explanation of those included in wireless communication circuit 111 described above, with “wireless communication circuit 111” replaced by “power line communication circuit 113”, “voltage monitoring circuit 112” replaced by “voltage monitoring circuit 114”, and “CMU 101” replaced by “CMU 102”.

Amplification circuit 134 is a circuit that amplifies signals to be transmitted to BMU 201.

Amplification circuit 135 is a circuit that amplifies signals received from BMU 201.

Capacitors 136 and 137 block the direct current component superimposed on the signal from BMU 201 received by power line communication.

Coil 138 superimposes signals to be transmitted from CMU 102 to BMU 201 onto the power line, and extracts signals transmitted from BMU 201 to CMU 102 that are superimposed on the power line.

As illustrated in FIG. 2, CMU 102 may include LED 133, for example. For example, LED 133 emits light when power line communication circuit 113 satisfies a specific condition.

As illustrated in FIG. 4B, voltage monitoring circuit 114 includes voltage conversion circuit (Reg.) 141, timer circuit (Timer) 142, communications interface (Com. I/F) 145, encryption circuit (Encryption) 147, switch 148, and comparators 149 to 152.

The explanation of the functions of voltage conversion circuit 141, timer circuit 142, communications interface 145, encryption circuit 147, and switch 148 included in voltage monitoring circuit 114 is the same as the explanation of those included in voltage monitoring circuit 112 described above, with “wireless communication circuit 111” replaced by “power line communication circuit 113”, “voltage monitoring circuit 112” replaced by “voltage monitoring circuit 114”, and “CMU 101” replaced by “CMU 102”.

Comparators 149 to 152 are provided one-to-one with respect to the plurality of battery cells 11. Here, four comparators 149 to 152 are illustrated as one example, but the number of comparators corresponds to the number of battery cells 11. For example, when four battery cells 11 are connected in series as the plurality of battery cells 11, comparator 149 compares the voltage of the first battery cell 11 with a predetermined voltage, comparator 150 compares the voltage of the second battery cell 11 with a predetermined voltage, comparator 151 compares the voltage of the third battery cell 11 with a predetermined voltage, and comparator 152 compares the voltage of the fourth battery cell 11 with a predetermined voltage. In this way, by providing comparators one-to-one with respect to the plurality of battery cells 11, voltage monitoring circuit 114 can determine whether each of the plurality of battery cells 11 is greater than or equal to a predetermined voltage (for example, whether it is overcharged) or whether each of the plurality of battery cells 11 is less than or equal to a predetermined voltage (for example, whether the voltage is too low). Stated differently, voltage monitoring circuit 114 can determine whether the voltage of each of the plurality of battery cells 11 is anomalous or not.

CMU 102 determines whether the voltage of each of the plurality of battery cells 11 is anomalous or not using voltage monitoring circuit 114, and transmits the determination result to BMU 201 using power line communication circuit 113.

CMU 102 may include voltage monitoring circuit 112 instead of voltage monitoring circuit 114. Stated differently, CMU 102 may detect the voltage value of each of the plurality of battery cells 11, and transmit the detected voltage values to BMU 201. CMU 101 may include voltage monitoring circuit 114 instead of voltage monitoring circuit 112. Stated differently, CMU 101 may determine whether the voltage of each of the plurality of battery cells 11 is anomalous or not, and transmit the determination result to BMU 201.

As illustrated in FIG. 2, CMU 301 includes current measurement circuit 311 that monitors current flowing in the battery assembly. CMU 301 includes power supply circuit 312 and insulated communication circuit 313.

Power supply circuit 312 is a circuit for supplying power to CMU 301, and supplies to CMU 301 power that has been supplied from BMU 201. For example, power supply circuit 312 is supplied with power from BMU 201 via transformer 501.

Insulated communication circuit 313 is a circuit for performing communication between CMU 301 and BMU 201 while maintaining insulation between CMU 301 and BMU 201. For example, insulated communication circuit 313 can perform communication between CMU 301 and BMU 201 while maintaining insulation between CMU 301 and BMU 201 by using transformer 502.

Current measurement circuit 311 is a circuit that measures current flowing in the battery assembly. More specifically, current measurement circuit 311 measures the current flowing in power line 405, that is, the current flowing in the battery assembly, by measuring the voltage generated when current flows through shunt resistor 402 provided on power line 405. As illustrated in FIG. 5, current measurement circuit 311 includes amplification circuit 321, AD converter (ADC) 322, and communications interface (Com. I/F) 323.

Amplification circuit 321 amplifies the voltage generated across shunt resistor 402. Amplification circuit 321 is provided because the resistance value of shunt resistor 402 is extremely small, and the voltage generated across shunt resistor 402 is also small.

AD converter 322 converts the voltage value (analog value) generated across shunt resistor 402 into a digital value.

Communications interface 323 is an interface for performing communication between CMU 301 and BMU 201.

As illustrated in FIG. 2, BMU 201 includes wireless communication circuit 211 and communication antenna ANT2 for communicating with CMU 101, as well as power line communication circuit 212 for communicating with CMU 102. BMU 201 also includes a micro controller unit (MCU) 213 for managing the battery assembly. Note that wireless communication circuit 211, power line communication circuit 212, and MCU 213 may be implemented by a single IC (for example, a single MCU). BMU 201 includes power supply circuit 215 and insulated communication circuit 216.

Power supply circuit 215 is a circuit for supplying power to CMU 301. For example, power supply circuit 215 supplies power to CMU 301 via transformer 501.

Insulated communication circuit 216 is a circuit for performing communication between CMU 301 and BMU 201 while maintaining insulation between CMU 301 and BMU 201. For example, insulated communication circuit 216 can perform communication between CMU 301 and BMU 201 while maintaining insulation between CMU 301 and BMU 201 by using transformer 502.

CMU 301 monitors the current flowing in the high-voltage battery assembly of several hundred volts and handles high voltages, whereas BMU 201 handles voltages of only a few volts. Therefore,

CMU 301 and BMU 201 are insulated by being connected via transformers 501 and 502.

As illustrated in FIG. 6A, wireless communication circuit 211 includes voltage conversion circuit (Reg.) 221, timer circuit (Timer) 222, communications interface (Com. I/F) 223, clock generation circuit (Clock gen) 224, phase-locked loop (PLL) 225, modulation circuit (Modulator) 226, transmission circuit (Tx) 227, demodulation circuit (Demodulator) 228, reception circuit (Rx) 229, communication error determination circuit (RF Error) 231, and wake-up circuit (Wake up) 232. FIG. 6A illustrates “IDOA” as the identification information of wireless communication circuit 211.

Voltage conversion circuit 221 is a circuit that converts the voltage input from any power source to a voltage for operating wireless communication circuit 211 and outputs the converted voltage.

Timer circuit 222 is a circuit that counts time.

Communications interface 223 is an interface for performing communication between wireless communication circuit 211 and MCU 213. Note that when wireless communication circuit 211 and MCU 213 are implemented by a single IC, communications interface 223 may be omitted.

Clock generation circuit 224 is a circuit for generating a clock in BMU 201.

Phase-locked loop 225 is a circuit that adjusts the phase of a local signal to match the phase of a received signal.

Modulation circuit 226 is a circuit that modulates signals to be transmitted to CMU 101.

Transmission circuit 227 is a circuit for transmitting signals to CMU 101. Transmission circuit 227 transmits signals to CMU 101 via communication antenna ANT2.

Demodulation circuit 228 is a circuit that demodulates signals received from CMU 101.

Reception circuit 229 is a circuit for receiving signals from CMU 101.

Reception circuit 229 receives signals from CMU 101 via communication antenna ANT2.

Communication error determination circuit 231 is a circuit that determines whether an anomaly has occurred in the communication between CMU 101 and BMU 201.

Wake-up circuit 232 is a circuit for activating MCU 213.

As illustrated in FIG. 2 and FIG. 6B, power line communication circuit 212 includes voltage conversion circuit (Reg.) 221, timer circuit (Timer) 222, communications interface (Com. I/F) 223, clock generation circuit (Clock gen) 224, phase-locked loop (PLL) 225, modulation circuit (Modulator) 226, demodulation circuit (Demodulator) 228, communication error determination circuit (RF Error) 231, wake-up circuit (Wake up) 232, amplification circuits 234 and 235, capacitors 236 and 237, and coil 238. FIG. 6B illustrates “IDOB” as the identification information of power line communication circuit 212.

The explanation of the functions of voltage conversion circuit 221, timer circuit 222, communications interface 223, clock generation circuit 224, phase-locked loop 225, modulation circuit 226, demodulation circuit 228, communication error determination circuit 231, and wake-up circuit 232 included in power line communication circuit 212 is the same as the explanation of those included in wireless communication circuit 211 described above, with “wireless communication circuit 211” replaced by “power line communication circuit 212”, and “CMU 101” replaced by “CMU 102”.

Amplification circuit 234 is a circuit that amplifies signals to be transmitted to CMU 102.

Amplification circuit 235 is a circuit that amplifies signals received from CMU 102.

Capacitors 236 and 237 block the direct current component superimposed on the signal from CMU 102 received by power line communication.

Coil 238 superimposes signals to be transmitted from BMU 201 to CMU 102 onto the power line, and extracts signals transmitted from BMU 201 to CMU 102 that are superimposed on the power line.

As illustrated in FIG. 6C, MCU 213 includes encryption circuit (Encryption) 241, identification circuit (ID identification circuit) 242, encryption circuit (Encryption) 243, and identification circuit (ID identification circuit) 244. MCU 213 is connected to a controller area network (CAN), and a firewall is provided between MCU 213 and the CAN. MCU 213 also stores table (table of cell position and RF com. ID) 245 showing the correspondence between the positions of each of the plurality of battery cells 11 in battery pack 10 and identification information such as the wireless communication circuit of the CMU of each battery pack 10.

Encryption circuit 241 is a circuit that encrypts and decrypts signals. For example, encryption circuit 241 decrypts signals (for example, voltage values of battery cell 11) transmitted from CMU 101, using an encryption key (Key).

Identification circuit 242 uses table 245 to identify which position of battery cell 11 in which battery pack 10 the voltage value of battery cell 11 included in the signal transmitted from CMU 101 corresponds to.

Encryption circuit 243 is a circuit that encrypts and decrypts signals. For example, encryption circuit 241 decrypts signals (for example, the determination result of whether the voltage of battery cell 11 is anomalous) transmitted from CMU 102, using an encryption key (Key).

Identification circuit 244 uses table 245 to identify which position of battery cell 11 in which battery pack 10 the voltage determination result of battery cell 11 included in the signal transmitted from CMU 102 corresponds to.

With the above circuit configuration, BMS 1 of the first example operates as follows.

When BMU 201 obtains the states (for example, voltage values) of the plurality of battery cells 11 monitored by the CMU assigned with the identification information “ID2A”, it broadcasts a request signal to cause the CMU assigned with the identification information “ID2A” to transmit the monitoring results to BMU 201.

CMU 101 receives the request signal, and because the identification information included in the request signal matches its own identification information “ID2A”, it determines that the request signal is addressed to itself, and performs processing to transmit the monitoring results of the plurality of battery cells 11 that it monitors to BMU 201. More specifically, CMU 101 obtains the voltage value of each of the plurality of battery cells 11 using multiplexer 143, and transmits to BMU 201 each voltage value, information indicating which position of battery cell 11 among the plurality of battery cells 11 each voltage value corresponds to, and the identification information of CMU 101. For example, depending on which battery cell 11 multiplexer 143 selected when obtaining the voltage value, it is possible to identify which position of battery cell 11 among the plurality of battery cells 11 the voltage value corresponds to.

BMU 201 receives, as a response to the request signal, information indicating the voltage values of the plurality of battery cells 11 monitored by CMU 101 and the identification information of CMU 101 from CMU 101. BMU 201 can identify which position of battery cell 11 in which battery pack 10 each of the voltage values of the plurality of battery cells 11 corresponds to by matching these pieces of information with table 245.

When BMU 201 obtains the states (for example, determination results of voltage anomalies) of the plurality of battery cells 11 monitored by CMU 102, it transmits a request signal to cause CMU 102 to transmit the monitoring results to BMU 201.

CMU 102 receives the request signal and performs processing to transmit the monitoring results of the plurality of battery cells 11 that it monitors to BMU 201. More specifically, CMU 102 determines whether the voltage of each of the plurality of battery cells 11 is anomalous or not using comparators 149 to 152, and transmits to BMU 201 the determination result of whether the voltage of each of the plurality of battery cells 11 is anomalous, information indicating which position of battery cell 11 among the plurality of battery cells 11 each determination result corresponds to, and the identification information of CMU 102. For example, depending on which comparator obtained the voltage for the determination result, it is possible to identify which position of battery cell 11 among the plurality of battery cells 11 the determination result of voltage anomaly corresponds to.

BMU 201 receives, as a response to the request signal, information indicating the anomaly determination results of the voltages of the plurality of battery cells 11 monitored by CMU 102 and the identification information of CMU 102 from CMU 102. BMU 201 can identify which position of battery cell 11 in which battery pack 10 each of the anomaly determination results for the voltages of the plurality of battery cells 11 corresponds to by matching these pieces of information with table 245.

When BMU 201 obtains the state (for example, current flowing through the battery assembly) of the battery assembly monitored by CMU 301, it transmits a request signal to cause CMU 301 to transmit the monitoring results to BMU 201.

CMU 301 receives the request signal and performs processing to transmit the monitoring results of the battery assembly that it monitors to BMU 201. More specifically, CMU 301 measures the current flowing in the battery assembly and transmits it to BMU 201. With this, BMU 201 can obtain the current flowing in the battery assembly.

As described above, in the first example, CMU 101 and CMU 102 each monitor the same battery cells 11, and regarding information about battery cells 11, CMU 101 is capable of communicating with BMU 201 via wireless communication circuit 111 and communication antenna ANT1, while CMU 102 is capable of communicating with BMU 201 via power line communication circuit 113. Stated differently, regarding information about battery cells 11, even if there is an anomaly in the wireless communication between CMU 101 and BMU 201, power line communication can be performed between CMU 102 and BMU 201. Furthermore, regarding information about battery cells 11, even if there is an anomaly in the power line communication between CMU 102 and BMU 201, wireless communication can be performed between CMU 101 and BMU 201. This increases the redundancy of communication within BMS 1.

Since wireless communication is susceptible to effects such as noise, if all communication between BMU 201 and CMUs 101 and 102 were wireless communication, there would be a risk that both the communication between BMU 201 and CMU 101 and the communication between BMU 201 and CMU 102 could fail. However, since wired communication is less susceptible to effects such as noise, by having the communication between BMU 201 and CMU 102 be wired power line communication, it is possible to inhibit both the communication between BMU 201 and CMU 101 and the communication between BMU 201 and CMU 102 from failing.

Wired communication requires wiring harnesses, and as wired communication increases, the number of wiring harnesses increases. Therefore, if all communication between BMU 201 and CMUs 101 and 102 were wired communication, the system would scale larger. However, by making the communication between BMU 201 and CMU 101 wireless communication, the increase in wiring harnesses can be inhibited.

### Second Example

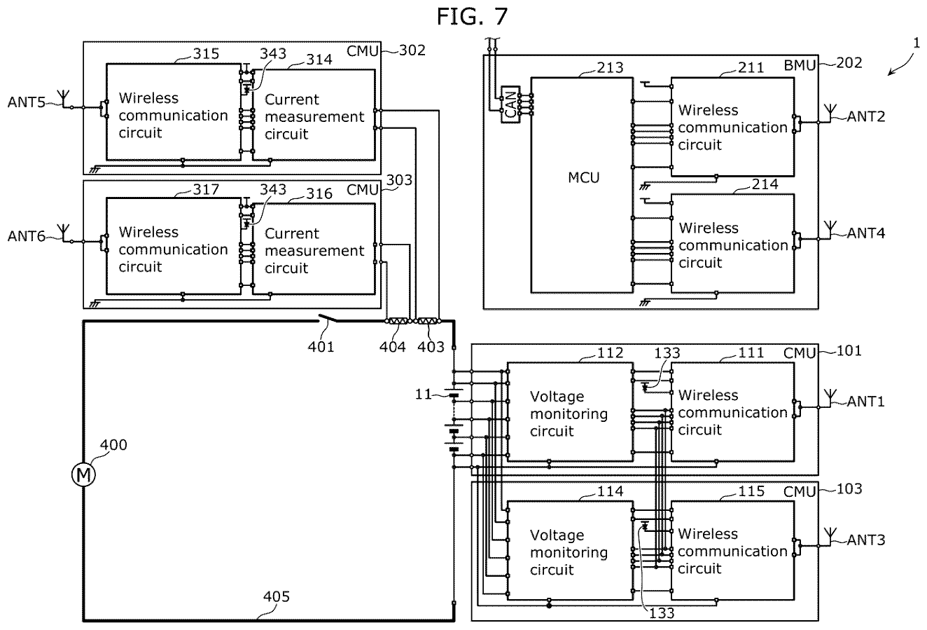

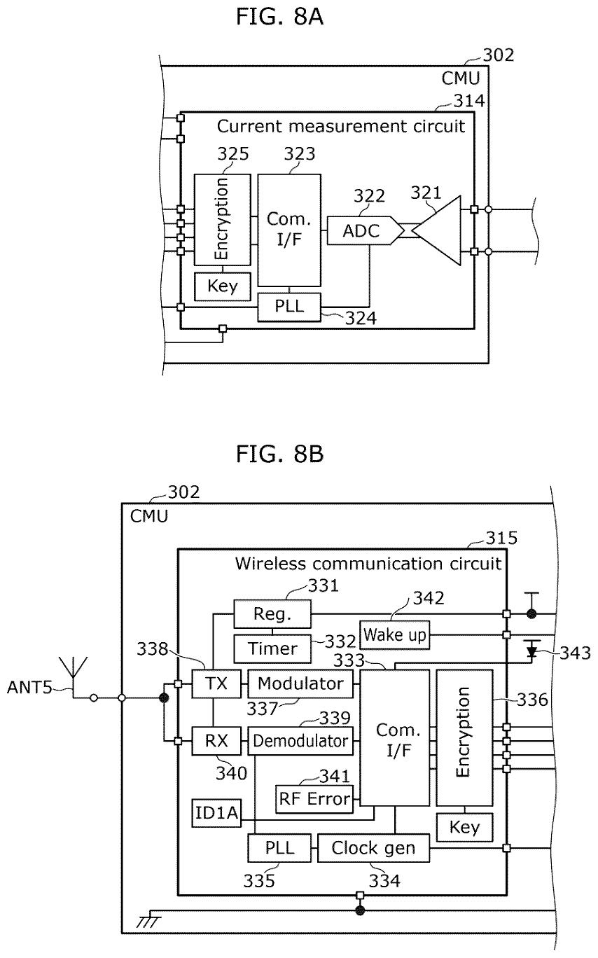

Next, the second example will be explained with reference to FIG. 7 through FIG. 8B.

FIG. 7 is a configuration diagram illustrating a second example of BMS 1 according to an embodiment of the present disclosure.

FIG. 8A is a configuration diagram illustrating one example of current measurement circuit 314 included in the first current monitoring circuit (CMU 302). Note that FIG. 8A also illustrates elements peripheral to current measurement circuit 314 in the configuration diagram of FIG. 7.

FIG. 8B is a configuration diagram illustrating one example of wireless communication circuit 315 included in the first current monitoring circuit (CMU 302). Note that FIG. 8B also illustrates elements peripheral to wireless communication circuit 315 in the configuration diagram of FIG. 7.

In the second example, focusing on one battery pack 10 among the plurality of battery packs 10, FIG. 7 illustrates a plurality of battery cells 11 included in one battery pack 10 in the battery assembly as the one or more battery cells included in the battery assembly. CMUs 101 and 103 as well as CMUs 302 and 303 are illustrated as monitoring circuit 100, and BMU 202 is illustrated as management circuit 200. Motor 400 is illustrated as a load to which power is supplied from the battery assembly. Power line 405 (bus bar) connecting the battery assembly and motor 400, and relay 401 as well as shunt resistors 403 and 404 inserted in power line 405 are also illustrated.

Relay 401 is a switch for interrupting current flowing in power line 405. For example, relay 401 is turned off to interrupt current flowing in power line 405 when the current monitored by CMU 302 or 303 is determined to be anomalous. Also, for example, relay 401 is turned off to interrupt current flowing in power line 405 when the voltage monitored by CMU 101 or 103 is determined to be anomalous.

Shunt resistors 403 and 404 are resistors for measuring current flowing in power line 405.

CMUs 101 and 103 are examples of a plurality of cell monitoring circuits that monitor one or more battery cells included in the battery assembly. Here, two cell monitoring circuits (CMUs 101 and 103) are illustrated as a plurality of cell monitoring circuits, but the number of cell monitoring circuits may be three or more, as illustrated in FIG. 1. For example, CMUs 101 and 103 monitor the voltage of each of the plurality of battery cells 11. Here, an example is given where CMU 101 and CMU 103 each monitor the same battery cells 11 (specifically, battery cells 11 included in same battery pack 10), but CMU 101 and CMU 103 may each monitor different battery cells 11 (specifically, battery cells 11 included in different battery packs 10).

Each of the plurality of cell monitoring circuits is connected to another cell monitoring circuit via wired communication. Here, as illustrated in FIG. 7, CMU 101 is connected to CMU 103 via wired communication, or in other words, CMU 103 is connected to CMU 101 via wired communication.

At least two of the plurality of cell monitoring circuits include a wireless communication circuit and a communication antenna for communicating with management circuit 200. Here, as illustrated in FIG. 7, CMU 101 includes wireless communication circuit 111 and communication antenna ANT1 for communicating with BMU 202, and CMU 103 includes wireless communication circuit 115 and communication antenna ANT3 for communicating with BMU 202. CMU 101 includes voltage monitoring circuit 112, and CMU 103 includes voltage monitoring circuit 114.

The explanation of the functions of wireless communication circuit 111 and voltage monitoring circuit 112 is the same as the explanation of wireless communication circuit 111 and voltage monitoring circuit 112 in the first example, with “BMU 201” replaced by “BMU 202”.

The explanation of the functions of wireless communication circuit 115 is the same as the explanation of wireless communication circuit 111 in the first example, with “voltage monitoring circuit 112” replaced by “voltage monitoring circuit 114”, “communication antenna ANT1” replaced by “communication antenna ANT3”, “CMU 101” replaced by “CMU 103”, and “BMU 201” replaced by “BMU 202”.

The explanation of the functions of voltage monitoring circuit 114 is the same as the explanation of voltage monitoring circuit 114 in the first example, with “power line communication circuit 113” replaced by “wireless communication circuit 115”, “CMU 102” replaced by “CMU 103”, and “BMU 201” replaced by “BMU 202”.

CMU 302 is one example of a first current monitoring circuit that measures current flowing in the battery assembly. As illustrated in FIG. 7, CMU 302 includes current measurement circuit 314 that measures current flowing in the battery assembly. CMU 302 includes wireless communication circuit 315 and communication antenna ANT5 for communicating with BMU 202. For example, wireless communication circuit 315 and current measurement circuit 314 are each implemented by different Note ICs. Note that wireless communication circuit 315 and current measurement circuit 314 may be implemented by a single IC.

As illustrated in FIG. 8A, current measurement circuit 314 includes amplification circuit 321, AD converter (ADC) 322, communications interface (Com. I/F) 323, phase-locked loop (PLL) 324, and encryption circuit (Encryption) 325.

Amplification circuit 321 amplifies the voltage generated across shunt resistor 403. Amplification circuit 321 is provided because the resistance value of shunt resistor 403 is extremely small, and the voltage generated across shunt resistor 403 is also small.

AD converter 322 converts the voltage value (analog value) generated across shunt resistor 403 into a digital value.

Communications interface 323 is an interface for performing communication between wireless communication circuit 315 and current measurement circuit 314. Note that when wireless communication circuit 315 and current measurement circuit 314 are implemented by a single IC, communications interface 323 may be omitted.

Phase-locked loop 324 is a circuit that adjusts the phase of a local signal to match the phase of a received signal.

Encryption circuit 325 is a circuit that encrypts and decrypts signals. For example, encryption circuit 325 encrypts signals to be transmitted to wireless communication circuit 315 and ultimately to BMU 202, using an encryption key (Key).

As illustrated in FIG. 8B, wireless communication circuit 315 includes voltage conversion circuit (Reg.) 331, timer circuit (Timer) 332, communications interface (Com. I/F) 333, clock generation circuit (Clock gen) 334, phase-locked loop (PLL) 335, encryption circuit (Encryption) 336, modulation circuit (Modulator) 337, transmission circuit (Tx) 338, demodulation circuit (Demodulator) 339, reception circuit (Rx) 340, communication error determination circuit (RF Error) 341, and wake-up circuit (Wake up) 342. FIG. 8B illustrates “ID1A” as the identification information of wireless communication circuit 315.

Voltage conversion circuit 331 is a circuit that converts the voltage input from any power source to a voltage for operating wireless communication circuit 315 and outputs the converted voltage.

Timer circuit 332 is a circuit that counts time.

Communications interface 333 is an interface for performing communication between wireless communication circuit 315 and current measurement circuit 314. Note that when wireless communication circuit 315 and current measurement circuit 314 are implemented by a single IC, communications interface 333 may be omitted.

Clock generation circuit 334 is a circuit for generating a clock in CMU 302.

Phase-locked loop 335 is a circuit that adjusts the phase of a local signal to match the phase of a received signal.

Encryption circuit 336 is a circuit that encrypts and decrypts signals. For example, encryption circuit 336 encrypts signals to be transmitted to BMU 202, using an encryption key (Key). Although CMU 302 includes encryption circuits 325 and 336 in current measurement circuit 314 and wireless communication circuit 315, respectively, CMU 302 need not include both encryption circuits 325 and 336. Stated differently, wireless communication circuit 315 need not include encryption circuit 336, or current measurement circuit 314 need not include encryption circuit 325.

Modulation circuit 337 is a circuit that modulates signals to be transmitted to BMU 202.

Transmission circuit 338 is a circuit for transmitting signals to BMU 202. Transmission circuit 338 transmits signals to BMU 202 via communication antenna ANT5.

Demodulation circuit 339 is a circuit that demodulates signals received from BMU 202.

Reception circuit 340 is a circuit for receiving signals from BMU 202. Reception circuit 340 receives signals from BMU 202 via communication antenna ANT5.

Communication error determination circuit 341 is a circuit that determines whether an anomaly has occurred in the communication between CMU 302 and BMU 202.

Wake-up circuit 342 is a circuit for activating current measurement circuit 314.

As illustrated in FIG. 7, CMU 302 may include LED 343, for example. For example, LED 343 emits light when wireless communication circuit 315 satisfies a specific condition.

CMU 303 is one example of a second current monitoring circuit that measures current flowing in the battery assembly. As illustrated in FIG. 7, CMU 303 includes current measurement circuit 316 that measures current flowing in the battery assembly. CMU 303 includes wireless communication circuit 317 and communication antenna ANT6 for communicating with BMU 202. For example, wireless communication circuit 317 and current measurement circuit 316 are each implemented by different ICs. Note that wireless communication circuit 317 and current measurement circuit 316 may be implemented by a single IC.

The explanation of the functions of current measurement circuit 316 is the same as the explanation of current measurement circuit 314, with “shunt resistor 403” replaced by “shunt resistor 404”, “current measurement circuit 314” replaced by “current measurement circuit 316”, and “wireless communication circuit 315” replaced by “wireless communication circuit 317”.

The explanation of the functions of wireless communication circuit 317 is the same as the explanation of wireless communication circuit 315, with “current measurement circuit 314” replaced by “current measurement circuit 316”, “wireless communication circuit 315” replaced by “wireless communication circuit 317”, “CMU 302” replaced by “CMU 303”, and “communication antenna ANT5” replaced by “communication antenna ANT6”. Note that the identification information of wireless communication circuit 317 is “ID1B”.

As illustrated in FIG. 7, BMU 202 includes wireless communication circuit 211 and communication antenna ANT2, as well as wireless communication circuit 214 and communication antenna ANT4, for communicating with CMUs 101 and 103 as well as CMUs 302 and 303. BMU 202 also includes MCU 213 for managing the battery assembly. Note that wireless communication circuits 211 and 214 as well as MCU 213 may be implemented by a single IC (for example, a single MCU).

The explanation of the functions of wireless communication circuit 211 is the same as the explanation of wireless communication circuit 211 in the first example, with “BMU 201” replaced by “BMU 202”, and “CMU 101” replaced by “CMU 101 or 103 or CMU 302 or 303”.

The explanation of the functions of wireless communication circuit 214 is the same as the explanation of wireless communication circuit 211 in the first example, with “BMU 201” replaced by “BMU 202”, “CMU 101” replaced by “CMU 101 or 103 or CMU 302 or 303”, and “communication antenna ANT2” replaced by “communication antenna ANT4”. Note that the identification information of wireless communication circuit 214 is “ID0B”.

As illustrated in FIG. 6C, MCU 213 includes encryption circuit (Encryption) 241, identification circuit (ID identification circuit) 242, encryption circuit (Encryption) 243, and identification circuit (ID identification circuit) 244. MCU 213 is connected to a controller area network (CAN), and a firewall is provided between MCU 213 and the CAN. MCU 213 also stores table (table of cell position and RF com. ID) 245 showing the correspondence between the positions of each of the plurality of battery cells 11 in battery pack 10 and identification information such as the wireless communication circuit of the CMU of each battery pack 10.

Encryption circuits 241 and 243 are circuits that encrypt and decrypt signals. For example, encryption circuits 241 and 243 decrypt signals transmitted from CMU 101 or 103 or CMU 302 or 303, using an encryption key (Key).

Identification circuits 242 and 244 use table 245 to identify which position of battery cell 11 in which battery pack 10 the voltage value of battery cell 11 included in the signal transmitted from CMU 101 corresponds to. Identification circuits 242 and 244 use table 245 to identify which position of battery cell 11 in which battery pack 10 the voltage determination result of battery cell 11 included in the signal transmitted from CMU 103 corresponds to.

With the above circuit configuration, BMS 1 of the second example operates as follows.

When BMU 202 obtains the states (for example, voltage values) of the plurality of battery cells 11 monitored by the CMU assigned with the identification information “ID2A”, it broadcasts a request signal to cause the CMU assigned with the identification information “ID2A” to transmit the monitoring results to BMU 202.

CMU 101 receives the request signal, and because the identification information included in the request signal matches its own identification information “ID2A”, it determines that the request signal is addressed to itself, and performs processing to transmit the monitoring results of the plurality of battery cells 11 that it monitors to BMU 202. More specifically, CMU 101 obtains the voltage value of each of the plurality of battery cells 11 using multiplexer 143, and transmits to BMU 202 each voltage value, information indicating which position of battery cell 11 among the plurality of battery cells 11 each voltage value corresponds to, and the identification information of CMU 101.

BMU 202 receives, as a response to the request signal, information indicating the voltage values of the plurality of battery cells 11 monitored by CMU 101 and the identification information of CMU 101 from CMU 101.

When BMU 202 obtains the states (for example, determination results of voltage anomalies) of the plurality of battery cells 11 monitored by the CMU assigned with the identification information “ID2B”, it broadcasts a request signal to cause the CMU assigned with the identification information “ID2B” to transmit the monitoring results to BMU 202.

CMU 103 receives the request signal, and because the identification information included in the request signal matches its own identification information “ID2B”, it determines that the request signal is addressed to itself, and performs processing to transmit the monitoring results of the plurality of battery cells 11 that it monitors to BMU 202. More specifically, CMU 103 determines whether the voltage of each of the plurality of battery cells 11 is anomalous or not using comparators 149 to 152, and transmits to BMU 202 the determination result of whether the voltage of each of the plurality of battery cells 11 is anomalous, information indicating which position of battery cell 11 among the plurality of battery cells 11 each determination result corresponds to, and the identification information of CMU 103.

BMU 202 receives, as a response to the request signal, information indicating the anomaly determination results of the voltages of the plurality of battery cells 11 monitored by CMU 103 and the identification information of CMU 103 from CMU 103.

When BMU 202 obtains the state (for example, current flowing in the battery assembly) of the battery assembly monitored by the CMU assigned with the identification information “ID1A”, it broadcasts a request signal to cause the CMU assigned with the identification information “ID1A” to transmit the monitoring results to BMU 202.

CMU 302 receives the request signal, and because the identification information included in the request signal matches its own identification information “ID1A”, it performs processing to transmit the monitoring results of the battery assembly that it monitors to BMU 202. More specifically, CMU 302 measures the current flowing in the battery assembly and transmits it to BMU 202. With this, BMU 202 can obtain the current flowing in the battery assembly.

When BMU 202 obtains the state (for example, current flowing in the battery assembly) of the battery assembly monitored by the CMU assigned with the identification information “ID1B”, it broadcasts a request signal to cause the CMU assigned with the identification information “ID1B” to transmit the monitoring results to BMU 202.

CMU 303 receives the request signal, and because the identification information included in request signal matches its own identification information “ID1B”, it performs processing to transmit the monitoring results of the battery assembly that it monitors to BMU 202. More specifically, CMU 303 measures the current flowing in the battery assembly and transmits it to BMU 202. With this, BMU 202 can obtain the current flowing in the battery assembly.

As described above, in the second example, at least two cell monitoring circuits (for example, CMU 101 and CMU 103) are capable of communicating with BMU 202 via wireless communication circuits and communication antennas. Therefore, even if there is an anomaly in the wireless communication between one of CMUs 101 and 103 and BMU 202, wireless communication can be performed between the other of CMUs 101 and 103 and BMU 202. This increases the redundancy of communication within BMS 1.

Two current monitoring circuits are provided, each capable of wireless communication with BMU 202, thereby increasing the redundancy of communication regarding the current monitoring results within BMS 1.

### Third Example

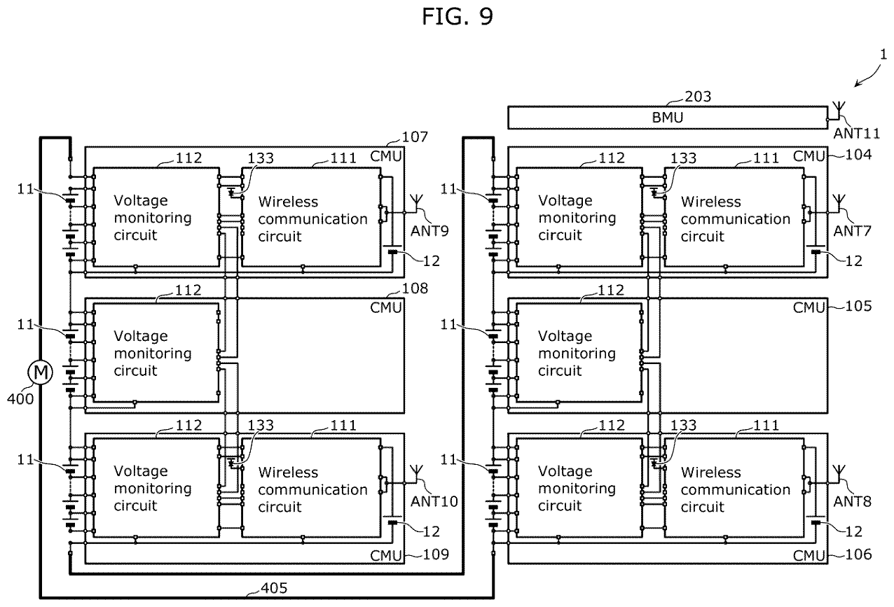

Next, the third example will be explained with reference to FIG. 9.

FIG. 9 is a configuration diagram illustrating a third example of BMS 1 according to an embodiment of the present disclosure.

In the third example, focusing on six battery packs 10 among the plurality of battery packs 10, FIG. 9 illustrates six sets of battery cells 11 included in one battery pack 10 in the battery assembly as the one or more battery cells included in the battery assembly. CMUs 104 to 109 are illustrated as monitoring circuit 100, and BMU 203 is illustrated as management circuit 200. Motor 400 is illustrated as a load to which power is supplied from the battery assembly, and power line 405 (bus bar) connecting the battery assembly and motor 400 is also illustrated.

CMUs 104 to 109 are examples of a plurality of cell monitoring circuits that monitor one or more battery cells included in the battery assembly. Here, six cell monitoring circuits (CMUs 104 to 109) are illustrated as a plurality of cell monitoring circuits, but the number of cell monitoring circuits is not particularly limited as long as it is two or more. For example, CMUs 104 to 109 monitor the voltage of each of the plurality of battery cells 11. Here, an example is given where each of CMUs 104 to 109 monitors different battery cells 11 (specifically, battery cells 11 included in different battery packs 10), but CMUs 104 to 109 may each monitor the same battery cells 11 (specifically, battery cells 11 included in the same battery pack 10).

Each of the plurality of cell monitoring circuits is connected to another cell monitoring circuit via wired communication. Here, as illustrated in FIG. 9, CMU 104 is connected to CMU 105 via wired communication, CMU 105 is connected to CMU 104 and CMU 106 via wired communication, CMU 106 is connected to CMU 105 via wired communication, CMU 107 is connected to CMU 108 via wired communication, CMU 108 is connected to CMU 107 and CMU 109 via wired communication, and CMU 109 is connected to CMU 108 via wired communication.

At least two of the plurality of cell monitoring circuits include a wireless communication circuit and a communication antenna for communicating with management circuit 200. Here, as illustrated in FIG. 9, CMU 104 includes wireless communication circuit 111 and communication antenna ANT7 for communicating with BMU 203, CMU 106 includes wireless communication circuit 111 and communication antenna ANT8 for communicating with BMU 203, CMU 107 includes wireless communication circuit 111 and communication antenna ANT9 for communicating with BMU 203, and CMU 109 includes wireless communication circuit 111 and communication antenna ANT10 for communicating with BMU 203. CMUs 104 to 109 include voltage monitoring circuit 112. CMUs 104, 106, 107, and 109 include battery 12. Even in a state where wireless communication circuit 111 is not receiving power supply from voltage monitoring circuit 112, specific functions included in wireless communication circuit 111 can be operated by battery 12.

The explanation of the functions of wireless communication circuit 111 and voltage monitoring circuit 112 of CMU 104 is the same as the explanation of wireless communication circuit 111 and voltage monitoring circuit 112 in the first example, with “communication antenna ANT1” replaced by “communication antenna ANT7”, “CMU 101” replaced by “CMU 104”, and “BMU 201” replaced by “BMU 203”. For example, the identification information of wireless communication circuit 111 of CMU 104 is “ID11”.

The explanation of the functions of wireless communication circuit 111 and voltage monitoring circuit 112 of CMU 106 is the same as the explanation of wireless communication circuit 111 and voltage monitoring circuit 112 in the first example, with “communication antenna ANT1” replaced by “communication antenna ANT8”, “CMU 101” replaced by “CMU 106”, and “BMU 201” replaced by “BMU 203”. For example, the identification information of wireless communication circuit 111 of CMU 106 is “ID12”.

CMU 105 does not include a wireless communication circuit and does not include a communication antenna, but since CMU 105 is connected to CMU 104 and CMU 106 via wired communication, CMU 105 can communicate with BMU 203 using either wireless communication circuit 111 and communication antenna ANT7 of CMU 104 or wireless communication circuit 111 and communication antenna ANT8 of CMU 106. The explanation of the functions of voltage monitoring circuit 112 of CMU 105 is basically the same as the explanation of voltage monitoring circuit 112 in the first example, with “CMU 101” replaced by “CMU 105” and “BMU 201” replaced by “BMU 203”.

The explanation of the functions of wireless communication circuit 111 and voltage monitoring circuit 112 of CMU 107 is the same as the explanation of wireless communication circuit 111 and voltage monitoring circuit 112 in the first example, with “communication antenna ANT1” replaced by “communication antenna ANT9”, “CMU 101” replaced by “CMU 107”, and “BMU 201” replaced by “BMU 203”. For example, the identification information of wireless communication circuit 111 of CMU 107 is “ID21”.

The explanation of the functions of wireless communication circuit 111 and voltage monitoring circuit 112 of CMU 109 is the same as the explanation of wireless communication circuit 111 and voltage monitoring circuit 112 in the first example, with “communication antenna ANT1” replaced by “communication antenna ANT10”, “CMU 101” replaced by “CMU 109”, and “BMU 201” replaced by “BMU 203”. For example, the identification information of wireless communication circuit 111 of CMU 109 is “ID22”.

CMU 108 does not include a wireless communication circuit and does not include a communication antenna, but since CMU 108 is connected to CMU 107 and CMU 109 via wired communication, CMU 108 can communicate with BMU 203 using either wireless communication circuit 111 and communication antenna ANT9 of CMU 107 or wireless communication circuit 111 and communication antenna ANT10 of CMU 109. The explanation of the functions of voltage monitoring circuit 112 of CMU 108 is basically the same as the explanation of voltage monitoring circuit 112 in the first example, with “CMU 101” replaced by “CMU 108” and “BMU 201” replaced by “BMU 203”.

BMU 203 includes communication antenna ANT11. Although the functional blocks of BMU 203 are omitted from illustration, BMU 203 includes wireless communication circuit 211 and MCU 213, as described in the first example. Wireless communication circuit 211 of BMU 203 communicates with CMUs 104 to 109 via communication antenna ANT11.

With the above circuit configuration, BMS 1 of the third example operates as follows.

When BMU 203 obtains the states (for example, voltage values) of the plurality of battery cells 11 monitored by the CMU assigned with the identification information “ID11”, it broadcasts a request signal to cause the CMU assigned with the identification information “ID11” to transmit the monitoring results to BMU 203.

CMU 104 receives the request signal, and because the identification information included in the request signal matches its own identification information “ID11”, it determines that the request signal is addressed to itself, and performs processing to transmit the monitoring results of the plurality of battery cells 11 that it monitors to BMU 203. For example, when there is no anomaly in the wireless communication between CMU 104 and BMU 203, CMU 105 is configured to communicate with BMU 203 using wireless communication circuit 111 and communication antenna ANT7 of CMU 104. In such cases, CMU 104 causes CMU 105, which is connected to CMU 104 via wired communication, to perform processing to transmit the monitoring results of the plurality of battery cells 11 that CMU 105 monitors to CMU 104. More specifically, CMUs 104 and 105 obtain the voltage value of each of the plurality of battery cells 11 using multiplexer 143, and CMU 104 transmits to BMU 203 each voltage value, information indicating which position of battery cell 11 among the plurality of battery cells 11 each voltage value corresponds to, and the identification information of CMU 104.

BMU 203 receives, as a response to the request signal, information indicating the voltage values of the plurality of battery cells 11 monitored by CMU 104 and CMU 105 and the identification information of CMU 104 from CMU 104.

Since CMU 106 is connected to CMU 104 via wired communication through CMU 105, in cases where there is an anomaly in the wireless communication between CMU 106 and BMU 203, CMU 104 can also transmit the monitoring results of the plurality of battery cells 11 that CMU 106 monitors to BMU 203.

When BMU 203 obtains the states (for example, voltage values) of the plurality of battery cells 11 monitored by the CMU assigned with the identification information “ID12”, it broadcasts a request signal to cause the CMU assigned with the identification information “ID12” to transmit the monitoring results to BMU 203.

CMU 106 receives the request signal, and because the identification information included in the request signal matches its own identification information “ID12”, it determines that the request signal is addressed to itself, and performs processing to transmit the monitoring results of the plurality of battery cells 11 that it monitors to BMU 203. More specifically, CMU 106 obtains the voltage value of each of the plurality of battery cells 11 using multiplexer 143, and CMU 106 transmits to BMU 203 each voltage value, information indicating which position of battery cell 11 among the plurality of battery cells 11 each voltage value corresponds to, and the identification information of CMU 106.

BMU 203 receives, as a response to the request signal, information indicating the voltage values of the plurality of battery cells 11 monitored by CMU 106 and the identification information of CMU 106 from CMU 106.

Since CMU 104 is connected to CMU 106 via wired communication through CMU 105, in cases where there is an anomaly in the wireless communication between CMU 104 and BMU 203, CMU 106 can also transmit the monitoring results of the plurality of battery cells 11 that CMU 104 and CMU 105 monitor to BMU 203.

Since the communication of the monitoring results of CMUs 107 to 109 can be performed in the same manner as CMUs 104 to 107, repeated explanation will be omitted.

As described above, in the third example, since each of the plurality of cell monitoring circuits (for example, CMUs 104 to 109) is connected to another cell monitoring circuit via wired communication, even cell monitoring circuits that do not include a wireless communication circuit and a communication antenna (for example, CMUs 105 and 108) can communicate with BMU 203 using wireless communication circuit 111 and the communication antenna included in another cell monitoring circuit connected via wired communication. Since at least two cell monitoring circuits (for example, CMU 104 and CMU 106) are capable of communicating with BMU 203 via wireless communication circuits 111 and communication antennas, even if there is an anomaly in the wireless communication between one of CMUs 104 and 106 and BMU 203, wireless communication can be performed between the other of CMUs 104 and 106 and BMU 203. This increases the redundancy of communication within BMS 1.

Since not all CMUs 104 to 109 need to include wireless communication circuit 111 and a communication antenna, wireless communication between BMU 203 and CMUs 104 to 109 can be realized at a low cost.

### Fourth and Fifth Examples

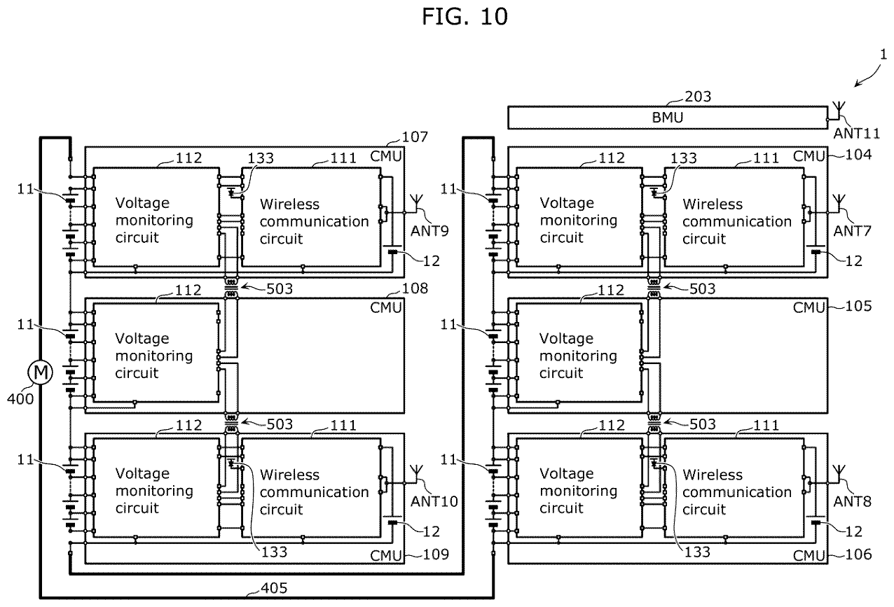

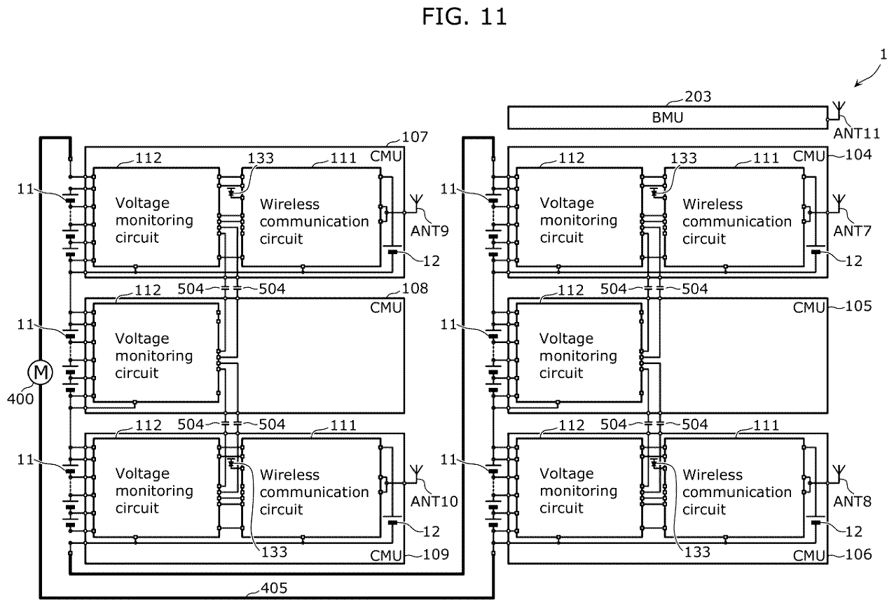

Next, the fourth and fifth examples will be explained with reference to FIG. 10 and FIG. 11.

FIG. 10 is a configuration diagram illustrating a fourth example of BMS 1 according to an embodiment of the present disclosure.

FIG. 11 is a configuration diagram illustrating a fifth example of BMS 1 according to an embodiment of the present disclosure.

BMS 1 according to the fourth and fifth examples differs from BMS 1 according to the third example in that each of the plurality of cell monitoring circuits (CMUs 104 to 109) is insulated from other cell monitoring circuits via an insulator. Since other aspects are the same as BMS 1 according to the third example, repeated explanation will be omitted.

In the fourth example, the insulators are exemplified as transformers 503 provided between CMU 104 and CMU 105, between CMU 105 and CMU 106, between CMU 107 and CMU 108, and between CMU 108 and CMU 109.

In the fifth example, the insulators are exemplified as capacitors 504 provided between CMU 104 and CMU 105, between CMU 105 and CMU 106, between CMU 107 and CMU 108, and between CMU 108 and CMU 109.

The magnitude of voltage applied to each of CMUs 104 to 109 differs according to the battery cells it monitors. Insulating the CMUs from each other can increase electrostatic discharge (ESD) resistance and reduce power consumption.

### OTHER EMBODIMENTS

One or more embodiments have been described above as one or more examples of the techniques according to the present disclosure. However, the techniques according to the present disclosure are not limited to these examples; various changes, substitutions, additions, omissions, etc., may be applied to the embodiments. For example, the following variations are also included in an embodiment of the present disclosure.

For example, in the first example, BMS 1 may include a plurality of cell monitoring circuits including CMUs 101 and 102, and each of the plurality of cell monitoring circuits may be connected to another cell monitoring circuit via wired communication. Stated differently, wired communication may be performed between the plurality of cell monitoring circuits. Here, as in the fourth and fifth examples, each of the plurality of cell monitoring circuits may be insulated from the other cell monitoring circuits via an insulator.

For example, in the first example, similar to the second example, two current monitoring circuits may be provided, and each of the two current monitoring circuits may include a wireless communication circuit and a communication antenna for communicating with management circuit 200.

In the above embodiment, each element included in BMS 1 may be configured using dedicated hardware, or may be implemented by executing a software program suitable for the element. Each element may be implemented by a program execution unit such as a CPU or processor reading and executing a software program recorded on a recording medium such as a hard disk or semiconductor memory.

Some or all of the functions of BMS 1 according to the embodiment are typically implemented as LSI circuits, which are integrated circuits. These elements may be integrated into individual chips, or a portion or all of the elements may be integrated into one chip. Circuit integration is not limited to LSI; the elements may be implemented using dedicated circuits or a general-purpose processor. A field programmable gate array (FPGA) which allows programming after manufacturing of the LSI circuits or a reconfigurable processor which allows reconfiguration of the connections and settings of circuit cells inside the LSI circuits may be used.

Furthermore, if a new technology for circuit integration that replaces LSI emerges due to advances in semiconductor technology or other derived technologies, it goes without saying that circuit integration of elements included in BMS 1 may be performed using that technology.

Embodiments arrived at by a person skilled in the art making various modifications to the embodiment, or embodiments realized by arbitrarily combining elements and functions in the embodiments which do not depart from the essence of the present disclosure are also included in the present disclosure.

### Additional Information

The following techniques are disclosed by the description of the above embodiment.

(Technique 1) A battery management system for managing a battery assembly includes: a management circuit that manages the battery assembly; a first cell monitoring circuit that monitors one or more battery cells included in the battery assembly; and a second cell monitoring circuit that monitors the one or more battery cells monitored by the first cell monitoring circuit. The first cell monitoring circuit includes a wireless communication circuit and a communication antenna for communicating with the management circuit, and the second cell monitoring circuit includes a power line communication circuit, for communicating with the management circuit, that uses a power line in the battery assembly.

With this, the first cell monitoring circuit and the second cell monitoring circuit each monitor the same battery cells, and regarding information about the battery cells, the first cell monitoring circuit is capable of communicating with the management circuit via a wireless communication circuit and a communication antenna, while the second cell monitoring circuit is capable of communicating with the management circuit via a power line communication circuit. Stated differently, regarding information about the battery cells, even if there is an anomaly in the wireless communication between the first cell monitoring circuit and the management circuit, power line communication can be performed between the second cell monitoring circuit and the management circuit. Furthermore, regarding information about the battery cells, even if there is an anomaly in the power line communication between the second cell monitoring circuit and the management circuit, wireless communication can be performed between the first cell monitoring circuit and the management circuit. This increases the redundancy of communication within the battery management system.

Since wireless communication is susceptible to effects such as noise, if all communication between the management circuit and the first and second cell monitoring circuits is made wireless, there is a risk that both the communication between the management circuit and the first cell monitoring circuit and the communication between the management circuit and the second cell monitoring circuit may fail. However, since wired communication is less susceptible to effects such as noise, by having the communication between the management circuit and the second cell monitoring circuit be wired power line communication, it is possible to inhibit both the communication between the management circuit and the first cell monitoring circuit and the communication between the management circuit and the second cell monitoring circuit from failing.

Wired communication requires wiring harnesses, and as wired communication increases, the number of wiring harnesses increases. Therefore, if all communication between the management circuit and the first cell monitoring circuit and second cell monitoring circuit were wired communication, the system would scale larger. However, by making the communication between the management circuit and the first cell monitoring circuit wireless communication, the increase in wiring harnesses can be inhibited.

(Technique 2) The battery management system according to Technique 1, including: a plurality of cell monitoring circuits including the first cell monitoring circuit and the second cell monitoring circuit. Each of the plurality of cell monitoring circuits is connected to one or more other cell monitoring circuits among the plurality of cell monitoring circuits via wired communication.

In this way, wired communication may be performed between the plurality of cell monitoring circuits.

(Technique 3) A battery management system for managing a battery assembly includes: a management circuit that manages the battery assembly; and a plurality of cell monitoring circuits that monitor one or more battery cells included in the battery assembly. Each of the plurality of cell monitoring circuits is connected to one or more other cell monitoring circuits among the plurality of cell monitoring circuits via wired communication, and at least two cell monitoring circuits among the plurality of cell monitoring circuits include a wireless communication circuit and a communication antenna for communicating with the management circuit.

With this, since each of the plurality of cell monitoring circuits is connected to another cell monitoring circuit via wired communication, even cell monitoring circuits that do not include a wireless communication circuit and a communication antenna can communicate with the management circuit using the wireless communication circuit and the communication antenna included in another cell monitoring circuit connected via wired communication. Since at least two cell monitoring circuits are capable of communicating with the management circuit via wireless communication circuits and communication antennas, even if there is an anomaly in the wireless communication between one of the at least two cell monitoring circuits and the management circuit, wireless communication can be performed between another of the at least two cell monitoring circuits and the management circuit. This increases the redundancy of communication within the battery management system.

Since not all of the plurality of cell monitoring circuits need to include a wireless communication circuit and a communication antenna, wireless communication between the management circuit and the plurality of cell monitoring circuits can be realized at a low cost.

(Technique 4) The battery management system according to Technique 2 or 3, wherein each of the plurality of cell monitoring circuits is insulated from the one or more other cell monitoring circuits via an insulator.

The magnitude of voltage applied to each of the plurality of cell monitoring circuits differs according to the battery cells it monitors. Insulating the cell monitoring circuits from each other can increase ESD resistance and reduce power consumption.

(Technique 5) The battery management system according to any one of Techniques 1 to 4, further including: a first current monitoring circuit and a second current monitoring circuit that measure current flowing in the battery assembly. The first current monitoring circuit and the second current monitoring circuit each include a wireless communication circuit and a communication antenna for communicating with the management circuit.

With this, two current monitoring circuits are provided, each capable of wireless communication with the management circuit, thereby increasing the redundancy of communication regarding the current monitoring results within the battery management system.

### INDUSTRIAL APPLICABILITY

The present disclosure is applicable to a battery management system or the like in which wireless communication is performed within the system.

1. A battery management system for managing a battery assembly, the battery management system comprising:
a management circuit that manages the battery assembly;
a first cell monitoring circuit that monitors one or more battery cells included in the battery assembly; and
a second cell monitoring circuit that monitors the one or more battery cells monitored by the first cell monitoring circuit, wherein
the first cell monitoring circuit includes a wireless communication circuit and a communication antenna for communicating with the management circuit, and
the second cell monitoring circuit includes a power line communication circuit, for communicating with the management circuit, that uses a power line in the battery assembly.

2. The battery management system according to claim 1, comprising:
a plurality of cell monitoring circuits including the first cell monitoring circuit and the second cell monitoring circuit, wherein
each of the plurality of cell monitoring circuits is connected to one or more other cell monitoring circuits among the plurality of cell monitoring circuits via wired communication.

3. The battery management system according to claim 2, wherein
each of the plurality of cell monitoring circuits is insulated from the one or more other cell monitoring circuits via an insulator.

4. A battery management system for managing a battery assembly, the battery management system comprising:
a management circuit that manages the battery assembly; and
a plurality of cell monitoring circuits that monitor one or more battery cells included in the battery assembly, wherein
each of the plurality of cell monitoring circuits is connected to one or more other cell monitoring circuits among the plurality of cell monitoring circuits via wired communication, and
at least two cell monitoring circuits among the plurality of cell monitoring circuits include a wireless communication circuit and a communication antenna for communicating with the management circuit.

5. The battery management system according to claim 4, wherein
each of the plurality of cell monitoring circuits is insulated from the one or more other cell monitoring circuits via an insulator.

6. The battery management system according to claim 1, further comprising:
a first current monitoring circuit and a second current monitoring circuit that measure current flowing in the battery assembly, wherein
the first current monitoring circuit and the second current monitoring circuit each include a wireless communication circuit and a communication antenna for communicating with the management circuit.

7. The battery management system according to claim 4, further comprising:
a first current monitoring circuit and a second current monitoring circuit that measure current flowing in the battery assembly, wherein
the first current monitoring circuit and the second current monitoring circuit each include a wireless communication circuit and a communication antenna for communicating with the management circuit.
